(19) United States
(12) Patent Application Publication
(10) Pub. No.: US 2015/0368783 A1
(43) Pub. Date: Dec. 24, 2015

(54) DEPOSITION APPARATUS WITH GAS SUPPLY AND METHOD FOR DEPOSITING MATERIAL

(71) Applicants: Thomas Werner ZILBAUER, (US); Marcus BENDER, Hanau (DE); APPLIED MATERIALS, INC., Santa Clara, CA (US)

(72) Inventors: Thomas Werner ZILBAUER, Alzenau (DE); Marcus BENDER, Hanau (DE)

(73) Assignee: Applied Materials, Inc., Santa Clara, CA (US)

(21) Appl. No.: 14/767,275

(22) PCT Filed: Feb. 25, 2013
(86) PCT No.: PCT/EP2013/053720

§ 371 Date: Aug. 11, 2015

(51) Int. Cl. C23C 14/00; C23C 14/06; C23C 14/08

(52) U.S. Cl. CPC C23C 14/0036; C23C 14/0063; C23C 14/0047; C23C 14/081; C23C 14/083; C23C 14/086; C23C 14/0676; C23C 14/0652; C23C 14/0641; C23C 14/0694; C23C 14/06

(57) ABSTRACT

An apparatus for depositing a material on a substrate is described. The apparatus includes a vacuum chamber; a substrate receiving portion in the vacuum chamber for receiving the substrate during deposition of the material; a target support configured to hold a target during deposition of the material on the substrate; a plasma generating device in the vacuum chamber for generating a plasma between the substrate receiving portion and the target support; and a first gas inlet for providing a supersonic stream of a gas, wherein the gas inlet is directed towards the substrate receiving portion. Further, a method for depositing a material on a substrate in a vacuum chamber is described. The method includes forming a plasma between the substrate and a target; releasing particles from the target using the plasma; and directing a supersonic stream of gas towards the substrate surface, on which the material is to be deposited.

### TECHNICAL FIELD OF THE INVENTION

Embodiments of the present invention relate to a deposition apparatus and a method for depositing a material. Embodiments of the present invention particularly relate to a deposition apparatus having a vacuum chamber and a gas inlet and a method for depositing a material in a vacuum chamber.

### BACKGROUND OF THE INVENTION

Several methods are known for depositing a material on a substrate. For instance, substrates may be coated by a physical vapor deposition (PVD) process, such as a sputter process. Typically, the process is performed in a process apparatus or process chamber, where the substrate to be coated is located or guided through. A deposition material to be deposited on the substrate is provided in the apparatus. A plurality of materials may be used for deposition on a substrate; among them, ceramics may be used.

Coated materials may be used in several applications and in several technical fields. For instance, an application lies in the field of microelectronics, such as generating semiconductor devices. Also, substrates for displays are often coated by a PVD process. Further applications may include insulating panels, organic light emitting diode (OLED) panels, but also hard disks, CDs, DVDs and the like.

The substrates to be coated are arranged in or guided through a deposition chamber for performing the coating process. When performing a sputter deposition process, the deposition chamber provides a target on which the material to be deposited on the substrate is arranged. The target material is released from the target, for instance, by means of plasma generated in the vacuum chamber. The released particles deposit on the substrate and form the desired material layer.

However, in some applications, further materials are present in the deposition chamber. For instance, in the case that a reactive sputter process is performed, the target may be poisoned by a reactive gas present in the sputtering atmosphere. As the poisoning is difficult to control, this effect can lead to process instabilities such as arcing or low deposition rates. Also, the poisoning may lead to inferior layer properties of the deposited film.

In addition, in in-line deposition systems for subsequent film depositions of different materials, the interaction of surplus reactive gas between adjacent deposition chambers may have process deteriorating effects and may imply the need for additional, cost-intensive gas separation solutions between the process chambers.

In view of the above, it is an object of the present invention to provide a deposition apparatus and a method for depositing a material on a substrate that overcome at least some of the problems in the art.

### SUMMARY OF THE INVENTION

In light of the above, an apparatus for depositing a material on a substrate and a method for depositing material on a substrate according to the independent claims are provided. Further aspects, advantages, and features of the present invention are apparent from the dependent claims, the description, and the accompanying drawings.

According to one embodiment, an apparatus for depositing a material on a substrate is provided. The apparatus includes a vacuum chamber; a substrate receiving portion in the vacuum chamber for receiving the substrate during deposition of the material; a target support configured to hold a target during deposition the material on the substrate; a plasma generating device in the vacuum chamber for generating a plasma between the substrate receiving portion and the target support; and a first gas inlet for providing a supersonic stream of a gas, wherein the first gas inlet is directed towards the substrate receiving portion

According to another embodiment, a method of depositing a material on a substrate in a vacuum chamber is provided. The method includes forming a plasma between the substrate and a target; releasing particles from the target using the plasma; and directing a supersonic stream of a first gas towards the substrate surface, on which the material is to be deposited.

According to another embodiment, a method of depositing a material on a substrate in a vacuum chamber is provided. The method includes forming a plasma between the substrate and a target; releasing particles from the target using the plasma; and directing a supersonic stream of a reactive gas into the vacuum chamber. Further embodiments can be provided by a combination with dependent claims and embodiments from the specification.

Embodiments are also directed at apparatuses for carrying out the disclosed methods and include apparatus parts for performing each described method step. These method steps may be performed by way of hardware components, a computer programmed by appropriate software, by any combination of the two or in any other manner. Furthermore, embodiments according to the invention are also directed at methods by which the described apparatus operates. It includes method steps for carrying out every function of the apparatus.

### BRIEF DESCRIPTION OF THE DRAWINGS

So that the manner in which the above recited features of the present invention can be understood in detail, a more particular description of the invention, briefly summarized above, may be had by reference to embodiments. The accompanying drawings relate to embodiments of the invention and are described in the following:

FIG. 1 shows a schematic view of a deposition apparatus according to embodiments described herein;

FIG. 2 shows a schematic view of a gas inlet for a deposition apparatus according to embodiments described herein;

FIG. 3 shows a schematic view of a deposition apparatus during operation according to embodiments described herein;

FIG. 4a shows a section of a schematic view of a deposition apparatus during operation according to embodiments described herein;

FIG. 4b shows a section of a schematic view of a deposition apparatus during operation according to embodiments described herein;

FIG. 5 shows a flow chart of a method for depositing a material according to embodiments described herein; and

FIG. 6 shows a flow chart of a method for depositing a material according to embodiments described herein.

### DETAILED DESCRIPTION OF EMBODIMENTS

Reference will now be made in detail to the various embodiments of the invention, one or more examples of which are illustrated in the figures. Within the following description of the drawings, the same reference numbers refer to same components. Generally, only the differences with respect to individual embodiments are described. Each example is provided by way of explanation of the invention and is not meant as a limitation of the invention. Further, features illustrated or described as part of one embodiment can be used on or in conjunction with other embodiments to yield yet a further embodiment. It is intended that the description includes such modifications and variations.

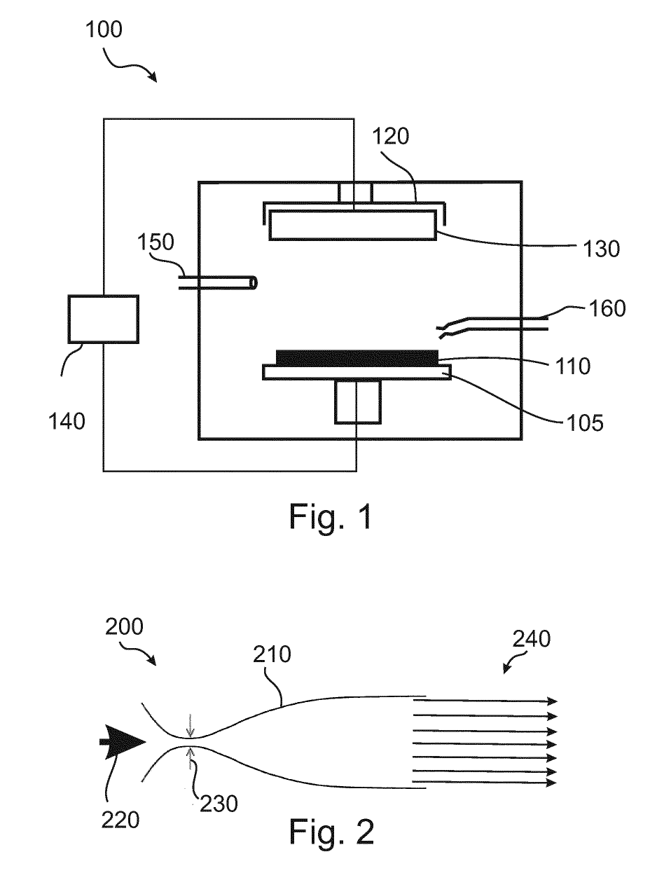

FIG. 1 shows a deposition chamber 100 for housing a deposition apparatus according to embodiments described herein. The deposition chamber may be a vacuum chamber. The vacuum referred to herein may for instance be a high vacuum with a pressure of about 0.5 Pa and a mean free path of about 5 cm.

The deposition apparatus according to embodiments described herein may include a target support 120, which is adapted for receiving a target 130. In some embodiments the target support may be adapted for supporting and/or driving a rotatable target. Further, the deposition apparatus as described herein may include a substrate receiving portion 105 for holding a substrate 110 during the deposition process.

While FIG. 1 shows the substrate receiving portion 105 as a sort of table or substrate support, on which the substrate 105 rests during the deposition process, the substrate receiving portion as described herein should be understood as being not limited to that kind of substrate receiving portion. Generally, the substrate receiving portion as described herein should be understood as being a portion of the apparatus for depositing a material, wherein the substrate to be coated is located in the substrate receiving portion during deposition. In some embodiments the substrate receiving portion may be a device being supportive for providing a substrate during the deposition. For instance, the substrate receiving portion may comprise a transport device for transporting the substrate through the chamber. The transport device of the substrate receiving portion may exemplarily comprise rolls and/or guide rails, such as magnetic guide rails for guiding the substrate through the deposition chamber. In some embodiments, the substrate receiving portion may be adapted for receiving a substrate carrier, which carries the substrate during the deposition process. For instance, the substrate receiving portion may be adapted to move the substrate and/or the substrate carrier through the deposition chamber. The moving substrate may be driven by a drive unit, such as a motor or the like. In some embodiments, the substrate to be transported may exemplarily be a web, a foil, or a substrate being moved past the source of deposition material, such as the target and/or further material supplies. In some embodiments described herein, a substrate may run through the apparatus without a local support in the system and the substrate receiving portion may be the space occupied by the substrate during deposition. For instance, when a flexible glass is processed, the roll on which the substrate is provided may be placed outside the deposition chamber keeping the glass stretched. The substrate may be guided through a slit in the walls of the deposition chamber to bring the substrate into the deposition chamber, and through the deposition chamber passing the deposition source (such as a target). After passing the deposition chamber, the substrate is exported from the deposition chamber via a slit in the deposition chamber wall. According to some embodiments, the slit in the deposition chamber may include a sort of lock for maintaining the vacuum in the deposition chamber.

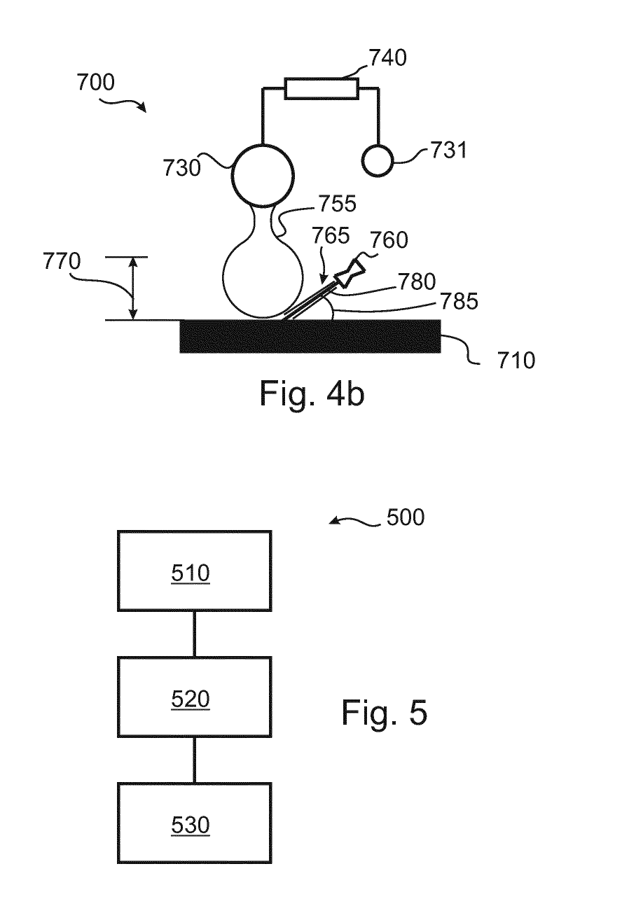

The deposition apparatus according to embodiments may include a power supply 140 for applying a voltage to a cathode (which may for instance be the target) and an anode (which may for instance be the substrate). As an example, the target is shown as a cathode and the substrate receiving portion is shown as an anode in FIG. 1. However, embodiments described herein are not limited to the arrangement having the target as a cathode and the substrate as an anode, which will be seen below with respect to FIGS. 4a and 4b. The applied voltage creates an electrical field in the vacuum chamber 100, which may be used to form plasma.

Vacuum chamber 100 according to embodiments described herein may have a first gas inlet 160 for supplying gas towards the substrate surface to be coated. The first gas inlet 160 may be directed to the substrate receiving portion 105 in order to provide a first gas to the substrate during the deposition process. A second gas supply 150 may be provided for supplying gas to be turned into plasma within the vacuum chamber 100 (for instance a noble gas, such as argon).

According to embodiments described herein, the first gas inlet 160 for supplying gas to be supplied towards the surface to be coated is a gas inlet adapted for providing a supersonic stream of gas. In some embodiments, the gas to be provided in a supersonic gas stream may be supplied by an array of specially designed nozzles, which direct and focus the gas stream to the substrate. The number of nozzles in a nozzle array may typically be between about 2 and about 200, more typically between about 10 and about 150, and even more typically between about 20 and about 120. The gas supplied by the first gas inlet providing a supersonic stream of gas may be a reactive gas, which is useful in the deposition process by, for instance, including a component (or a precursor of a component) of the material to be deposited.

The supersonic stream of gas directed towards the surface to be coated helps preventing, or at least minimizing, target poisoning and surplus reactive gas in the vacuum chamber.

According to embodiments described herein, a convergent-divergent nozzle (for instance, a Laval nozzle) is provided in the first gas inlet to provide a directed, super-sonic gas jet. Generally, the convergent-divergent nozzle should be understood as a nozzle having a convergent portion and a divergent portion. According to some embodiments, the gas to be supplied in a supersonic stream firstly passes the convergent portion of the nozzle, and then passes the divergent portion of the nozzle. Within the super-sonic gas jet, the gas molecules have a significantly increased momentum, compared to gas molecules in a subsonic gas stream. The relatively high momentum of the gas molecules in a gas stream as provided by the gas inlet according to embodiments described herein helps to minimize the lateral dispersion of the gas stream. Also, the relatively high momentum helps to focus the gas stream to an area on the substrate surface, where the gas should be provided for the deposition of films with desired stoichiometry. The focusing of the gas stream and the minimized dispersion of the supersonic gas stream results in the supersonic gas stream having a main direction. For instance, if the first gas inlet for providing a supersonic gas stream is directed towards a substrate, the main direction of the supersonic gas stream is towards the substrate. In some embodiments, typically between about 75% to about 100%, more typically between about 80% to about 99%, and even more typically between about 85% to about 98% of the gas molecules in the gas stream flow in the main direction.

According to some embodiments, the main direction runs along a course leading from the first gas inlet to the substrate. For instance, the course along which the main direction runs may substantially be a virtual line from the gas inlet to the substrate surface. In some embodiments, the virtual line of the main direction may hit the substrate surface to be coated at an angle of between about 0° to about 89°, more typically between about 5° and about 85°, and even more typically between about 10° and 80°. In one example, the virtual line of the main direction may hit the substrate surface to be coated at an angle of between about 10° to about 50°.

According to embodiments described herein, the angle is measured between the substrate surface and the main direction of the supersonic gas stream, whereby an angle of 0° would indicate a supersonic gas stream being provided substantially parallel to the substrate surface, and an angle of 90° would indicate a supersonic gas stream being provided substantially perpendicular to the substrate surface.

With embodiments described herein, it is possible to provide the right amount of reactive gas for completing the surface reaction during stoichiometric film growth. Due to the fact that the supersonic stream of gas prevents lateral dispersion, the collateral target poisoning as well as the reactive gas consumption may be minimized.

In some embodiments, the gas to be supplied towards the surface to be coated is a reactive gas for a reactive sputter process performed within the vacuum chamber 100. By directing the first gas supply adapted for supplying a supersonic gas stream towards the substrate, it is possible to provide sufficiently enough gas, such as reactive gas, at the substrate surface to support reactions at the surface during the deposition process.

According to embodiments described herein, a reactive gas as described herein should be understood as a gas, which may provide a reaction with other materials being present in the vacuum chamber. For instance, the reactive gas may be chosen so as to react with particles released from the target. As an example, the reactive gas may be oxygen, nitrogen, or any suitable gas, or an activated gas, which may react with the released particles of the target material. In some embodiments, the reactive and/or activated gas to be supplied in a supersonic stream of gas may include neutral, ionized, excited, and/or radicalized materials. According to some embodiments, which may be combined with other embodiments described herein, the supersonic gas stream may include oxygen containing gases (for example O₂, H₂O, R—OH), nitrogen providing gases (for example N₂, N₂O, NH₃), fluorine providing gases (for example SF₆, R—F) and/or further materials such as ArH or the like.

In some embodiments, the material to be deposited on the substrate may be composed of a target material, or parts of a target material, such as particles released from the target, and the reactive gas, or at least components of the reactive gas.

For instance, with a deposition apparatus and a method according to embodiments described herein, materials may be deposited on a substrate including oxides, nitrides, or oxy-nitrides, such as MOₓ, MNₓ MOₓN_{y}, where M may stand for Al, Si, Nb, Ti, Mo, MoNb_{z}, AlNd_{z}, In, Sn, Zn, AlZn_{z}, InGa_{z1}Zn_{z2}, InSn_{z}, LiPz, LiCOz. Further, materials to be deposited on a substrate in embodiments described herein may include fluorides, such as MgFₓ, AlFₓ, and R—F organics (such as Teflon). In embodiments described herein, x, y, and z are to be understood as indices describing a variation in stoichiometry. Some examples of materials to be deposited may thus include materials like ITO, SiO₂, Nb₂O₅, or TiO₂.

Although embodiments described herein generally refer to a reactive sputter process, it should be understood that the apparatus and the method described herein may also be adapted to any vacuum processes, where gases are provided at a defined position in the vacuum chamber, while the point of gas inlet is positioned at some distance to a further reaction zone, such as a target surface, in order to avoid contamination.

Further, the deposition process and apparatus may be combined with or applied in several further variations of the deposition process, such as DC sputtering processes, HF sputtering processes, a magnetron sputtering processes, or a rotary target process.

As used herein, “magnetron sputtering” refers to sputtering performed using a magnetron, i.e. a magnet assembly, that is, a unit capable of generating a magnetic field. Typically, such a magnet assembly consists of one or more permanent magnets. These permanent magnets are typically arranged within a rotatable target or coupled to a planar target in a manner such that the free electrons are trapped within the generated magnetic field generated below the rotatable target surface. For rotatable targets, magnet assemblies may be provided within a backing tube or with the target material tube. Such a magnet assembly may also be arranged coupled to a planar target. For planar targets, a magnet can be provided on a side of a backing plate opposing the target material. According to typical implementations, magnetron sputtering can be realized by a double magnetron cathode such as, but not limited to, a TwinMag cathode assembly. Particularly, for MF sputtering (middle frequency sputtering) from a target, target assemblies including double cathodes can be applied. According to typical embodiments, the cathodes in a deposition chamber may be interchangeable. Accordingly, the targets are changed after the material to be sputtered has been consumed. According to embodiments herein, middle frequency is a frequency in the range of 0.5 kHz to 350 kHz, for example, 10 kHz to 50 kHz.

According to different embodiments, which can be combined with other embodiments described herein, sputtering can be conducted as DC sputtering, MF (middle frequency) sputtering, as RF sputtering, or as pulse sputtering. As described herein, some deposition processes might beneficially apply MF, DC or pulsed sputtering. However, other sputtering methods can also be applied.

FIG. 2 shows an example of a nozzle 200 being part of a first gas inlet for a supersonic stream of gas according to embodiments described herein. The nozzle 200 may for instance be used in the first gas inlet 160 of vacuum chamber 100 shown in FIG. 1. The nozzle may be formed in order to provide a supersonic gas stream into the chamber. For instance, the nozzle may be a Laval nozzle.

In some embodiments, the walls 210 of the nozzle 200 may be formed so as to guide the gas stream with supersonic speed to the deposition chamber. As exemplarily shown in FIG. 2, the gas is supplied in a stream 220 to the nozzle. In some embodiment, the gas stream 220 supplied to the nozzle 200 may come from a gas piping system or from a gas source. The gas stream 220 flows into the nozzle and is guided by the geometry of the nozzle 200.

According to some embodiments, the nozzle 200 provides a critical diameter 230. The nozzle 200 may be formed so that the gas stream in the nozzle reaches sonic speed at the critical diameter 230. In embodiments of the nozzle described herein, the gas stream in the nozzle is accelerated to supersonic speed after the critical diameter. The gas stream leaves the nozzle 200 in a supersonic gas stream 240. In some embodiments, the nozzle 200 leads the gas stream 240 directly to a deposition chamber, such as the deposition chamber 100 described above. In some embodiments, the nozzle 200 is part of a gas inlet piping system, which is adapted to lead the supersonic gas stream 240 to a deposition chamber.

As can be seen in FIG. 2, the supersonic gas stream 240 leaves the nozzle 200 in substantially one direction (such as the main direction as described above) due to the fact that the supersonic gas stream has a minimized lateral dispersion. The supersonic gas stream 240 leaving the nozzle 200 substantially in the main direction, may be directed towards the substrate to be coated and flows to the substrate without significantly deviating from the main direction so that typically between about 75% to about 100%, more typically between about 80% to about 99%, and even more typically between about 85% to about 98% of the gas molecules in the gas stream flow in the main direction and towards the substrate surface.

In some embodiments, and as described above, the deposition chamber may be a vacuum chamber having a pressure of about 0.5 Pa. Based on exemplary process parameters, the following rough estimation of dimensions for a nozzle may be derived. For instance, if oxygen is used as a reactive gas for reacting with the particles released from the target at the substrate surface, if a pressure of about 0.5 Pa is present in the deposition chamber, if a typical nozzle inlet pressure of 100 Pa after the mass flow control is provided, and if a typical gas flow of 50 sccm of O₂ or ArO₂ is supplied (for instance via an array of 20 nozzles), the critical area (smallest area) of each nozzle may have about 8E-3 mm², corresponding to 0.1 mm critical diameter (narrowest nozzle point), which may result in a supersonic gas stream with a velocity of about 300 m/s. According to some embodiments, these values may also be used when providing an array of several nozzles, such as a linear array of nozzles. For instance, a linear array of nozzles may include about 50 nozzles.

In some examples, a higher nozzle inlet pressure (such as an inlet pressure of about 1000 Pa) may lead to a critical diameter of each individual nozzle in a nozzle array of about 30 microns. An arrangement having a nozzle inlet pressure of about 1000 Pa and a critical diameter of about 30 microns may result in a supersonic gas jet having a gas velocity of about 1000 m/s.

Generally, the critical diameter of the convergent-divergent nozzle depends on the inlet and outlet pressure, the gas flow to be provided and the number of nozzles to distribute the required process flow. According to some embodiments, the at least one convergent-divergent nozzle of a gas inlet as described herein may have a critical diameter of typically about 1 micron to about 4 mm, more typically about 30 microns to about 1 mm and even more typically about 60 microns to about 0.2 mm.

For the typical dimensions and the above described vacuum level, this situation corresponds to a Knudson number of about 0.5 to 2. Regarding the gas dynamics aspect, this is still within the transition flow regime getting close to the molecular flow (kinetic) regime. For these cases, a special simulation of the gas behavior may be used to determine the behavior of gas distribution after the Laval nozzle exhaust, such as DSMC (Direct Simulation Monte Carlo).

According to some embodiments, the corresponding longitudinal dimensions and details on the opening scheme of the nozzle may be determined by calculations and simulations, which may exemplarily be based on the above given examples of parameters. For instance, the longitudinal dimension and the opening scheme may be determined so as to achieve an optimized effect with respect to the gas flow and the nozzle inlet pressure.

The nozzle described herein may be adapted for accelerating a reactive gas to supersonic speed. According to some embodiments, the material as well as the geometry of the nozzle may be adapted in order to allow reactive gases to be accelerated to supersonic speed. The material may exemplarily be substantially resistant (or at least resistant for a predetermined time period) against reactive gases used in a reactive sputter process, and especially against reactive gases at velocities of sonic speed or above. For instance, the nozzles in the embodiment described herein, may be formed by scribing the shape into metal or a semiconductor material. The scribing may exemplarily be performed by a laser technique or by an ion-beam scribing technique. Alternatively, and especially for larger sizes of the nozzle, the nozzle according to embodiments described herein, may be made from glass or a metal capillary. In some embodiments, and especially for smaller sizes of the nozzle, the nozzle may be produced by Micro-Electro-Mechanical Systems (MEMS) or Complementary Metal Oxide Semiconductor (CMOS) techniques, such as techniques used for ink jet nozzle production.

In one process example for a small critical diameter of the nozzle, the gas is supplied to the nozzle with a pressure of about 1E4 Pa, which corresponds to 0.1 atm (for instance gas stream 220 in FIG. 2). The gas supplied may in this example be H₂O provided in a gas flow of about 5 sccm via a number of 150 convergent-divergent nozzles. The critical diameter of the nozzle used for the first example is about 1 micron. The outlet pressure of the supersonic gas stream at the nozzle outlet (such as gas stream 240 in FIG. 2) is about 0.5 Pa and the resulting gas velocity at the nozzle outlet is about 4300 m/s (corresponding to about 370 Mach).

In an example of a typical SiO₂ process, the gas is supplied to the nozzle with a pressure of about 600 Pa. The gas supplied may in this example be O₂ provided in a gas flow of about 120 sccm via a number of 20 convergent-divergent nozzles. The critical diameter of the nozzle used for the first example is about 60 micron. The outlet pressure of the supersonic gas stream at the nozzle outlet (such as gas stream 240 in FIG. 2) is about 0.2 Pa and the resulting gas velocity at the nozzle outlet is about 1200 m/s (corresponding to about 110 Mach).

In an example of a large critical diameter, the gas is supplied to the nozzle with a pressure of about 10 Pa. The gas supplied may in this example be SF₆ provided in a gas flow of about 200 sccm via one convergent-divergent nozzle. The critical diameter of the nozzle used for the first example is about 4 mm. The outlet pressure of the supersonic gas stream at the nozzle outlet (such as gas stream 240 in FIG. 2) is about 1 Pa and the resulting gas velocity at the nozzle outlet is about 25 m/s (corresponding to about 1.9 Mach)

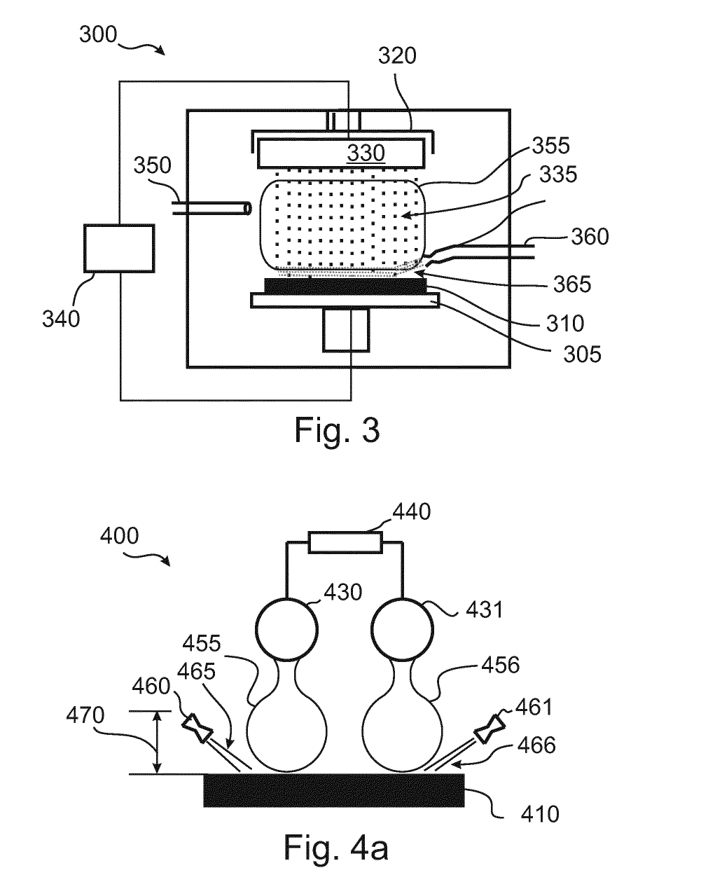

FIG. 3 shows a deposition chamber 300 during a deposition process. The deposition chamber 300 may include a power supply 340 for supplying power to the substrate 310 and the target 330 in order to generate an electrical field in the deposition chamber 300. The substrate 310 to be coated with a material is exemplarily shown on a table-like substrate receiving portion 305. However, in some embodiments, and as mentioned before with respect to FIG. 1, the substrate receiving portion may be adapted for receiving and/or transporting a substrate moving through the deposition chamber during the deposition process.

The target 330 may include at least a component of the material to be deposited on the substrate surface, or a precursor of a component of the material to be deposited on the substrate surface. The component of the material to be deposited provided by the target may be referred to as target material. In the example shown in FIG. 3, plasma is formed in an area 355 in the deposition chamber 300. According to embodiments described herein, the plasma may be formed from the gas supplied by a second gas inlet 350. The plasma in the area 355 in the deposition chamber may reach the target and may release particles of target material 335. The target material particles 335 may then move to the substrate surface to be coated.

According to some embodiments, gas particles, such as reactive gas particles are supplied to the deposition chamber 300 by first gas inlet 360. As explained above, the first gas inlet 360 may provide a supersonic stream of gas, preferably a supersonic stream of reactive gas. The gas stream coming through the first gas inlet 360 is denoted with reference sign 365 (and is exemplarily shown by dotted, greyish lines). The supersonic gas stream may include a component, or a precursor of a component of the material to be deposited on the substrate surface. The supersonic stream of reactive gas 365 is directed towards the substrate and does not tend to spread in the deposition chamber. At the substrate surface, the target material particles 335 and the reactive gas stream 365 mix with each other and may react together. By the reaction of the target material particles and the gas particles supplied by the supersonic gas inlet, the material to be deposited forms and deposits on the substrate surface. According to some embodiments, the reaction may take place on the substrate surface or before the material to be deposited impinges on the substrate surface. According to some embodiments, and dependent on the geometry of the arrangement, the gas supplied in a supersonic stream of gas may partly ionize when passing through the plasma.

As can be seen in FIG. 3, the second gas inlet 350 is exemplarily arranged besides the target support 320. However, it should be understood that the arrangement of the second gas inlet is not limited to the exemplarily shown arrangement of the second gas inlet. Rather, the second gas inlet for supplying gas to be turned into plasma is generally arranged so that the plasma is formed substantially between the target support and the substrate receiving portion. For instance, the second gas inlet may be arranged at a side wall of the deposition chamber or the like.

Regarding the supersonic gas stream inlet, it should be understood that the supersonic gas stream inlet is formed so as to direct the gas, such as a reactive gas, towards the substrate. For instance, the outlet of the gas inlet itself may be directed towards the substrate so that the gas stream being guided through the gas inlet, is directed towards the substrate. According to some embodiments, the gas inlet is directed towards the substrate receiving portion so as to allow for and support a reaction of the gas supplied in the supersonic stream and the particles released from the target in the target support at the substrate surface or on the substrate surface.

According to some embodiments, the gas inlet for the supersonic gas stream may be directed towards the substrate surface so that typically more than about 20%, more typically more than about 30%, and even more typically more than about 40% of the reactive gas reacts with the target material particles at the substrate surface. In some embodiments, the term “at the substrate” or “at the substrate surface” may be understood as on the substrate surface or above the substrate surface, such as up to 50% of the height of the deposition chamber above the substrate surface.

FIG. 4a shows a partial side view of a deposition apparatus according to embodiments described herein. The deposition arrangement 400 may include targets 430, 431 which may, as described above, include at least a component of the material to be deposited on the substrate 410. A further component of the material to be deposited, or a precursor of a component of the material to be deposited, may be supplied to the deposition apparatus 400 by first gas inlets 460 and 461 providing supersonic gas streams 465 and 466. The gas of the supersonic gas stream may be a reactive gas, which may react at the surface of the substrate with particles released from the targets 430, 431 by plasmas 455, 456.

In FIG. 4a, the targets 430, 431 are shown as a pair of cathodes, each providing a deposition source, respectively. The pair of cathodes have an AC power supply 440, e.g. for MF sputtering, RF sputtering or the like. Particularly for large area deposition processes and for deposition processes on an industrial scale, MF sputtering can be conducted in order to provide desired deposition rates.

In FIG. 4a, the gas inlets 460 and 461 are exemplarily shown in a simplified way, indicating a nozzle geometry in the gas inlet as exemplarily described in FIG. 2. The shape of the plasmas 455 and 456 should also be understood as an example. Generally, the shape of the plasma may be influenced by the plasma generating device including, for instance, a second gas inlet and a power supply. The shape of the plasma may also be dependent on further components of the deposition chamber, or the target, such as a magnetron. In case a magnetron is used, mainly the target surface, which is substantially not in the plasma racetrack, may be poisoned by reactive gases present in the deposition chamber.

By the reactive gas stream 465 and 466 shown in FIG. 4a it can be seen how the reactive gas stream is directed towards the substrate, especially with respect to the target. According to some embodiments, the reactive gas streams 465 and 466 provided by the supersonic gas inlets 460 and 461, respectively, do substantially not reach the target, but only reach the desired reaction area 470 for reacting with particles released from the target by plasmas 455 and 456. In some embodiments, the reaction area 470 ranges from the substrate surface to a height of about 50% of the distance between the substrate surface and the target surface. In some embodiments, the reaction area 470 may range from the substrate surface to a height of about 30% of the distance between the substrate surface and the target surface. With the supersonic stream of gas being directed towards the substrate and being supplied to the reaction area as described herein, it is assured that the reactive gas does not have a negative impact on the deposition process, or minimizes at least a negative impact of the reactive gas on the deposition process.

FIG. 4b shows an embodiment of a deposition apparatus 700. The deposition apparatus 700 in FIG. 4b is similar to the deposition apparatus 400 in FIG. 4a. As can be seen in FIG. 4b, a cathode 730 and an anode 731 are provided, which are electrically connected to DC power supply 740. Sputtering from a target for e.g. a transparent conductive oxide film is typically conducted as DC sputtering. The cathode 730 is connected to the DC power supply 740 together with the anode 731 for collecting electrons during sputtering.

The remaining components of the deposition apparatus 700 may be a substrate 710, a plasma 755, a first gas supply 760 for providing a supersonic gas stream 765, and a reaction area 770, as described above with respect to FIGS. 1 to 4a.

In FIG. 4b, the virtual line 780 of the main direction of the supersonic gas stream 765 is shown, together with an angle 785 between the virtual line 780 of the main direction and the substrate 710, which is in detail described above with respect to FIG. 1.

FIG. 5 shows a flow chart of a method 500 for depositing a material on a substrate in a vacuum chamber according to embodiments described herein. The method may include, in block 510, forming a plasma between a substrate being present in a deposition chamber and a target in the deposition chamber. According to some embodiments, the plasma may be generated as described above with respect to FIGS. 1 to 4 by providing a plasma gas, such as Argon, in the deposition chamber, especially between the target and the substrate surface. Also, as described above, a power supply may be provided in the vacuum chamber for generating the plasma from the plasma gas supplied.

In some embodiments, the method of depositing a material may be performed in a high vacuum chamber, which may be a vacuum at a pressure of about 0.5 Pa.

In block 520, the plasma generated in block 510 is used for releasing particles from the target. The released particles may be referred to as target material and may be a component, or a precursor of a component, of the material to be deposited on the substrate. The particles released from the target may proceed to the substrate surface and/or a reaction area, such as reaction area 470 shown in FIG. 4.

Block 530 of method 500 describes a supersonic gas stream being directed towards the substrate surface, on which the material is to be deposited. In some embodiments, the supersonic stream of gas may be a supersonic stream of reactive gas. The supersonic stream of gas may, while being directed towards the substrate surface, be supplied to a reaction area as described above.

In some embodiments, the method for depositing material on a substrate may be a reactive sputter process. The materials used for the material deposition may be adapted for a reactive sputter process, such as the target material and the reactive gas supplied in a supersonic gas stream. For instance, the materials used may be materials for forming a layer of a material including oxides, nitrides, or oxy-nitrides, such as MOₓ, MNₓ MOₓN_{y}, where M may stand for Al, Si, Nb, Ti, Mo, MoNb_{z}, AlNd_{z}, In, Sn, Zn, AlZn_{z}, InGa_{z1}Zn_{z2}, InSn_{z}, LiPz, LiCOz. Further, materials to be deposited on a substrate in embodiments described herein may include fluorides, such as MgFₓ, AlFₓ, and R—F organics (such as Teflon). In embodiments described herein, x, y, and z are to be understood as indices describing a variation in stoichiometry. Some examples of materials to be deposited may thus include materials like ITO, SiO₂, Nb₂O₅, or TiO₂or the like on a substrate.

It should be understood that the gas to be altered in plasma (also referred to as plasma gas) for the deposition process is supplied to the vacuum chamber so that a plasma may be formed between the target and the substrate. For instance, the plasma gas may be supplied adjacent to the target, or from a side wall of the vacuum chamber as long as the plasma gas supply allows for forming a regular plasma in the desired area within the vacuum chamber. In particular, the plasma gas may be supplied so that the plasma is able to release a sufficient amount of target material particles from the target.

According to some embodiments, the supersonic gas stream may be supplied by a Laval nozzle having a geometry as exemplarily described above with respect to FIG. 2. The Laval nozzle may be part of a gas inlet for a reactive gas, in the case that a reactive sputter process is performed. The Laval nozzle may be connected to a gas source and/or a gas piping system. In some embodiments, the Laval nozzle may directly open out into the vacuum chamber. According to some embodiments, the Laval nozzle may open out into a gas pipe which leads the supersonic gas stream into the deposition chamber.

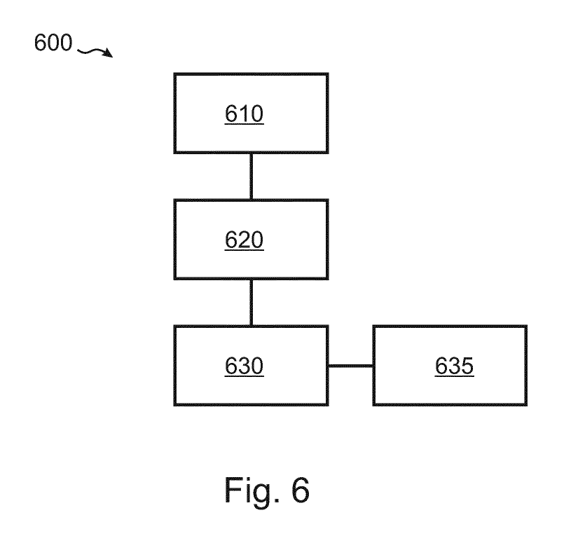

FIG. 6 shows a flow chart of a method 600 for depositing material on a substrate according to some embodiments described herein. In FIG. 6, the blocks 610, 620, and 630 may correspond to the blocks 510, 520, and 530 as described with respect to FIG. 5 above. The method 600 further includes block 635. In block 635, the supersonic stream of gas is directed towards the substrate so as to allow the gas supplied in the supersonic gas stream to react with particles released from a target in the target support during deposition. As described above, the reaction may take place in a reaction area.

In the reaction area, the particles released from the target mix with the supersonic stream of gas. The released particles including a component of the material to be deposited on the substrate and the gas particles in the supersonic gas stream may react with each other in order to form the material to be deposited on the substrate surface. According to some embodiments, the reaction of the particles released from the target and the gas particles may take place at the substrate surface, on the substrate surface and/or in the reaction area ranging from the substrate surface to a height of about 50% of the distance between the substrate surface and the target surface.

In some embodiments, directing the supersonic stream of the first gas includes directing the supersonic stream of gas towards the substrate surface by providing a supersonic gas stream having a main direction along a course running from the first gas inlet to the substrate surface to be coated. For instance, the course along which the main direction runs may substantially be a virtual line from the gas inlet to the substrate surface. In some embodiments, the virtual line of the main direction may hit the substrate surface to be coated at an angle of between about 0° to about 89°, more typically between about 5° and about 85°, and even more typically between about 10° and 80°. In one example, the virtual line of the main direction may hit the substrate surface to be coated at an angle of between about 10° to about 50°.

With embodiments described herein, less poisoning of the target, a higher deposition rate, enhanced process stabilities and, thus, better film uniformity may be achieved. The supply of a gas participating in the deposition, such as a reactive gas, and being provided in a supersonic gas stream towards the substrate allows for an effective deposition in a reactive sputter deposition process.

While the foregoing is directed to embodiments of the invention, other and further embodiments of the invention may be devised without departing from the basic scope thereof, and the scope thereof is determined by the claims that follow.

1. Apparatus for depositing a material on a substrate, comprising:
a vacuum chamber;
a substrate receiving portion in the vacuum chamber for receiving the substrate during deposition of the material;
a target support configured to hold a target during deposition of the material on the substrate;
a plasma generating device in the vacuum chamber for generating a plasma between the substrate receiving portion and the target support; and
a first gas inlet for providing a supersonic stream of a gas, wherein the first gas inlet is directed towards the substrate receiving portion.

2. The apparatus according to claim 1, wherein the apparatus is adapted for a reactive sputter deposition, and wherein the gas inlet is adapted for supplying a reactive gas for the reactive sputter deposition.

3. The apparatus according to claim 1, wherein the gas inlet is adapted to supply activated gas to the substrate.

4. The apparatus according to claim 1, wherein the gas inlet comprises a plurality of nozzles, each of which nozzles being adapted for providing a supersonic stream of gas.

5. The apparatus according to claim 1, wherein the material of the target and the gas supplied in a supersonic gas stream are chosen to form a material to be deposited on the substrate selected from the group consisting of MOₓ, MN_{X} MOₓN_{y}, MgFₓ, A1F_{X}, R—F organics, and Teflon, where M stands for a material selected from the group consisting of Al, Si, Nb, Ti, Mo, MoNb_{z}, AlNd_{z}, In, Sn, Zn, AlZn_{z}, InGa_{z1}Zn_{z2}, InSn_{z}, LiP_{z}, and LiCO_{z}.

6. The apparatus according to claim 1, wherein the first gas inlet is directed towards the substrate receiving portion by being arranged to provide a supersonic gas stream, which has a main direction along a course running from the first gas inlet to the substrate surface to be coated at an angle of between about 5° to about 85° to the substrate surface.

7. The apparatus according to claim 1, wherein the gas inlet comprises at least one convergent-divergent nozzle.

8. The apparatus according to claim 7, wherein the at least one convergent-divergent nozzle has a critical diameter of about 1 micron to about 4 mm.

9. The apparatus according to claim 1, wherein the plasma generating device comprises a second gas inlet for supplying gas to be turned into plasma between the target support and the substrate receiving portion for generating a plasma.

10. Method of depositing a material on a substrate in a vacuum chamber, comprising:
forming a plasma between the substrate and a target;
releasing particles from the target using the plasma (455); and
directing a supersonic stream of a first gas towards the substrate surface, on which the material is to be deposited.

11. The method according to claim 10, wherein the material is deposited on the substrate by reactive sputter deposition.

12. The method according to claim 10, wherein forming a plasma comprises supplying a second gas to be turned into plasma between the substrate and the target to form the plasma.

13. The method according to claim 10, wherein the supersonic stream of the first gas is supplied by at least one convergent-divergent nozzle.

14. The method according to claim 10, wherein the supersonic stream of the first gas comprises a reactive gas.

15. The method according to claim 10, wherein directing the supersonic stream of the first gas comprises directing the supersonic stream of gas towards the substrate surface by providing a supersonic gas stream, which has a main direction along a course running from the first gas inlet to the substrate surface to be coated at an angle of between about 5° to about 85° to the substrate surface.

16. The apparatus according to claim 3, wherein the gas inlet is adapted to supply activated gas to the substrate.

17. The apparatus according to claim 2, wherein the gas inlet comprises a plurality of nozzles, each of which nozzles being adapted for providing a supersonic stream of gas.

18. The apparatus according to claim 3, wherein the gas inlet comprises a plurality of nozzles, each of which nozzles being adapted for providing a supersonic stream of gas.

19. The apparatus according to claim 9, wherein the gas inlet comprises at least one convergent-divergent nozzle.

20. The method according to claim 15, wherein forming a plasma comprises supplying a second gas to be turned into plasma between the substrate to form the plasma.
